(19) United States
(12) Patent Application Publication
(10) Pub. No.: US 2007/0039543 A1
(43) Pub. Date: Feb. 22, 2007

(54) PHASE DELAY ELEMENT AND METHOD FOR PRODUCING A PHASE DELAY ELEMENT

(76) Inventor: Karl Heinz Schuster, Koenigsbronn (DE)

Correspondence Address: GRAY ROBINSON, P.A., 401 E. LAS OLAS BLVD., SUITE 1850, FT. LAUDERDALE, FL, 33301, US

(21) Appl. No.: 11/465,244

(22) Filed: Aug. 17, 2006

(30) Foreign Application Priority Data
Aug. 20, 2005 (DE) 10 2005 039 517.1

(51) Int. Cl. C30B 11/00

(52) U.S. Cl. 117/73

(57) ABSTRACT

The invention relates to a method for producing a zeroth-order or low-order phase delay element, in particular a phase delay element for wavelengths λ<200 nm, the phase delay element being formed from a birefringent crystalline material. In this case, an anisotropic crystal plate connected via a first connecting layer to a first carrier plate is connected to a second carrier plate on the side averted from the first carrier plate by means of a second connecting layer. The two connecting layers are sequentially removed, and an immersion liquid is respectively applied to the exposed surfaces of the anisotropic crystal plate and a support plate is mounted in each case.

### BACKGROUND OF THE INVENTION

1. Field of the Invention

The invention relates to a method for producing a zeroth-order or low-order phase delay element, in particular a phase delay element for wavelengths λ<200 nm, the phase delay element being formed from a birefringent crystalline material. The invention further relates to a zeroth-order or low-order phase delay element.

2. Description of the Related Art

Phase delay elements are optical components with the aid of which the polarization state of the light can be varied in a defined fashion. Zeroth-order phase delay elements, that is to say λ/4 elements and λ/2 elements, are required for semiconductor lithography with wavelengths λ<200 nm. It is only when appropriate phase delay elements are available that some mirror lens objectives or projection objectives for semiconductor lithography without central shielding and with a polarization optical divider reach their highest level of transmission.

In this case, a number of conditions are to be placed simultaneously on the phase delay elements, and these substantially restrict the design possibilities:

First and foremost, it is desirable to have a good transmittance for the exposure wavelengths of 157 nm, 193 nm and 248 nm. Furthermore, it is necessary for the selected materials to display a good radiation stability over the entire product lifetime. Use in an illumination system requires that the elements used must be insensitive to temperature changes with regard both to mechanics and to the phase delay.

Finally, the delay elements must largely retain their delay over a large angular range such that, above all, zeroth-order phase delay elements appear suitable for the applications named.

Various phase delay elements and variants in their production are known from the prior art.

For example, it is customary to use birefringent materials such as, for example, magnesium fluoride (MgF₂) or silicon dioxide (SiO₂) in phase delay elements. Since the materials named exhibit strongly birefringent properties, values in the range of a few μm result for the thickness of the plates to be used for the wavelengths considered in the range <200 nm. For lithography, the phase delay elements require minimum sizes in the range of 70×160 mm, for example, and/or a diameter of 150-200 mm, and so given the thicknesses named such phase delay elements are mechanically extremely unstable and can become unusable owing to very small external disturbances.

A first approach to solving this set of problems is shown in International Patent Application WO 2005/024474 A1, which goes back to the applicant. The abovenamed thin phase delay elements are mechanically stabilized according to the teaching of the quoted document in that the thin birefringent anisotropic crystal plate is wrung on a transparent carrier plate, it being possible to use a silica glass plate, for example, as carrier plate for the wavelengths of 193 nm and 248 nm. Here, the wringing forces as a rule transmit the thermal length changes of the substantially thicker carrier plate virtually completely onto the anisotropic crystal plate such that the latter follows the length changes in the carrier plate.

First and foremost, the single-axis birefringent crystal materials coming into consideration for the said application have the following properties:

Birefringence nₑ-nₒ:

| | 248.338 nm | 193.304 nm | 157.629 nm |
|---|---|---|---|
| Al₂O₃ (Sapphire) | −0.009763 | −0.011346 | −0.012973 |
| MgF₂ (Sellaite) | +0.012832 | +0.013609 | +0.014243 |
| SiO₂ (Silica) | +0.011121 | +0.013508 | 0.0185 |

Resulting thicknesses for a zeroth-order plate for
λ/4 (λ/2) [μm]:

| | 248.338 nm | 193.304 nm | 157.629 nm |
|---|---|---|---|
| Al₂O₃ (Sapphire) | 6.36 (12.72) | 4.26 (8.52) | 3.04 (6.08) |
| MgF₂ (Sellaite) | 4.84 (9.68) | 3.55 (7.10) | 2.76 (5.53) |
| SiO₂ (Silica) | 5.58 (11.17) | 3.58 (7.16) | 2.13 (4.26) |

Coefficient of thermal expansion:

| | Parallel to the | Perpendicular to |
|---|---|---|
| | principal | the principal |
| | crystallographic | crystallographic |
| | axis | axis |
| Al₂O₃ (Sapphire) | 6.65 * 10⁻⁶/K | 7.15 * 10⁻⁶/K |
| MgF₂ (Sellaite) | 9.4 * 10⁻⁶/K | 13.6 * 10⁻⁶/K |
| SiO₂ (Silica) | 12.38 * 10⁻⁶/K | 6.88 * 10⁻⁶/K |

A problem of the mode of procedure represented in WO 2005/024474 A1 consists, however, in that even very small contaminants between the carrier plate and anisotropic crystal plate suffice to at least locally raise the anisotropic crystal plate from the carrier plate. Since the thickness of the gap thus produced between the carrier plate and anisotropic crystal plate usually exceeds the range of the optical near field (approximately λ/10), a reduction in the transmission comes about in the regions raised by the contaminants. Because of the central significance of the dose observance for the quality of the lithography system, such effects are frequently no longer tolerable—particularly in the case of transmission glitches resulting thereby in the range >7%.

### SUMMARY OF THE INVENTION

It is therefore an object of the present invention to specify a mechanically stable phase delay element and a method for producing the latter, the aim being to avoid a damaging reduction of the transmission.

This object is achieved by means of a method according to Claim 1 and by a phase delay element according to Claim 11. The subclaims relate to advantageous further variants of the invention.

According to the invention, the anisotropic crystal plate is inserted between two support plates in a mechanically mounted fashion. This has the advantage that relatively large deformations of the anisotropic crystal plate can thereby be effectively avoided. The space between the support plates and the crystal plate is filled with an immersion liquid in order to avoid uncontrolled movements of the anisotropic crystal plate between the support plates. Here, it is advantageous to select the refractive index of the immersion liquid in the range of the refractive index of the ordinary beam nₒ and that of the extraordinary beam nₑ.

Exemplary embodiments of the invention are explained below by way of example with the aid of the drawings.

### BRIEF DESCRIPTION OF THE DRAWINGS

FIG. 1 shows an illustration of the anisotropic crystal plate cemented on a first carrier plate,

FIG. 2 shows an illustration of the anisotropic crystal plate between two carrier plates,

FIG. 3 shows an illustration of an intermediate step of the method according to the invention, and

FIG. 4 shows an illustration of an exemplary phase delay element according to the invention.

### DETAILED DESCRIPTION

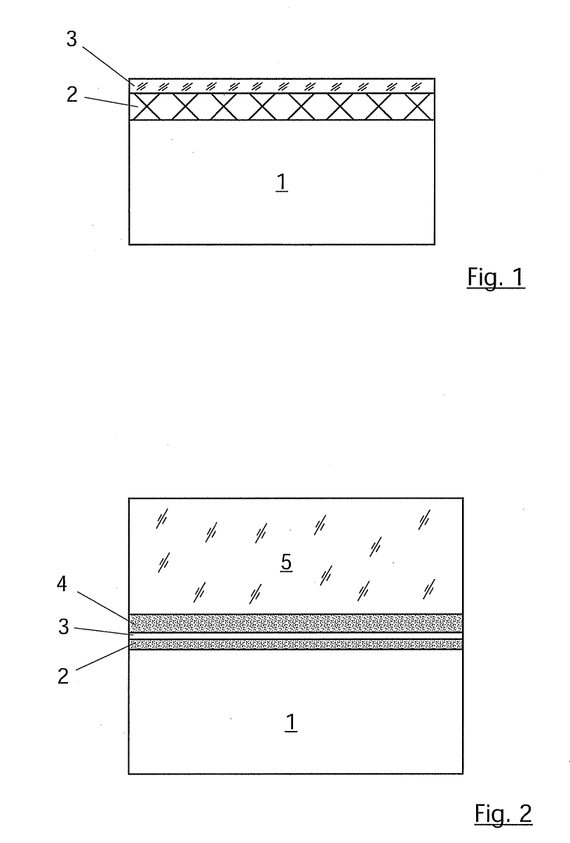

In order to produce the phase delay element according to the invention, the first step is to carry out the method represented in WO 2005/024474 A1 as far as the operational step after which an anisotropic crystal plate 3 has its final dimensions, thickness and plane parallelism (compare FIG. 1).

To this end, a first carrier plate 1 is produced which is provided with a plane-processed surface. The anisotropic crystal plate 3 is subsequently fabricated. Thereafter, the first carrier plate 1 is connected to the anisotropic crystal plate 3 via a first connecting layer 2. As illustrated, the connecting layer 2 can have a uniform thickness. However, it can also alternatively be of wedge shape.

Subsequently, a large part of the anisotropic crystal plate 3 is detached except for a residual layer, and the anisotropic crystal plate 3 is removed except for an end thickness by means of further production and polishing methods.

FIG. 1 shows the anisotropic crystal plate 3 after this step. In this stage of the method, it is connected to a first carrier plate 1 via a first connecting layer 2 which consists, for example, of an organic adhesive (cement).

In this state, the crystal plate 3 has a thickness of, for example, approximately 7.16 μm and exhibits no fabrication artefacts. To aid a clear explanation, the dimensions of the parts in FIG. 1 and also in FIGS. 2 to 4 are represented in a greatly enlarged fashion. The connecting layer 2 is typically selected to be thin, since the organic adhesive has an E module which is low by comparison with the first carrier plate 1. The thin connecting layer 2 therefore has the effect that it is possible during the preceding fabrication steps for the thin anisotropic crystal plate 3 to be stabilized mechanically in an optimum fashion by the first carrier plate 1. The small dimensions, thus resulting, of the outer end faces of the first connecting layer 2 lead, however, to the fact that the latter is accessible to a chemical decomposition only with difficulty, and its dissolution in a chemical bath, for example, proceeds comparatively slowly.

The second connecting layer 4 which is subsequently to be applied on the side of the anisotropic crystal plate 3 averted from the first carrier plate 1 (illustrated in FIG. 2) is thus to be selected thicker as far as possible, for example in a range of 0.2 mm-0.5 mm, in order to ensure a rapid dissolution in a solvent bath. It connects the finished side of the anisotropic crystal plate 3 to a second carrier plate 5, which can consist, in particular, of silica glass.

After the curing of the second connecting layer 4, the first carrier plate 1 is detached from the crystal plate 3 in the region of the first connecting layer 2 by means of a flat saw or with the aid of a wire saw.

Any remaining residues of the carrier plate 1 can be removed by a subsequent lapping operation in order to expose the first connecting layer 2. After the lapping operation, the anisotropic crystal plate 3 is, as previously, protected from mechanical influences between the two connecting layers 2 and 4.

The exposed first connecting layer 2 can now be removed gently with the aid of a rag soaked in solvent. It is important in this case that the materials of the two connecting layers 2 and 4 can be dissolved as far as possible by means of different solvents. In other words, the removal of the first connecting layer 2, which is as alcohol-stable as possible, is not intended to attack the second connecting layer 4.

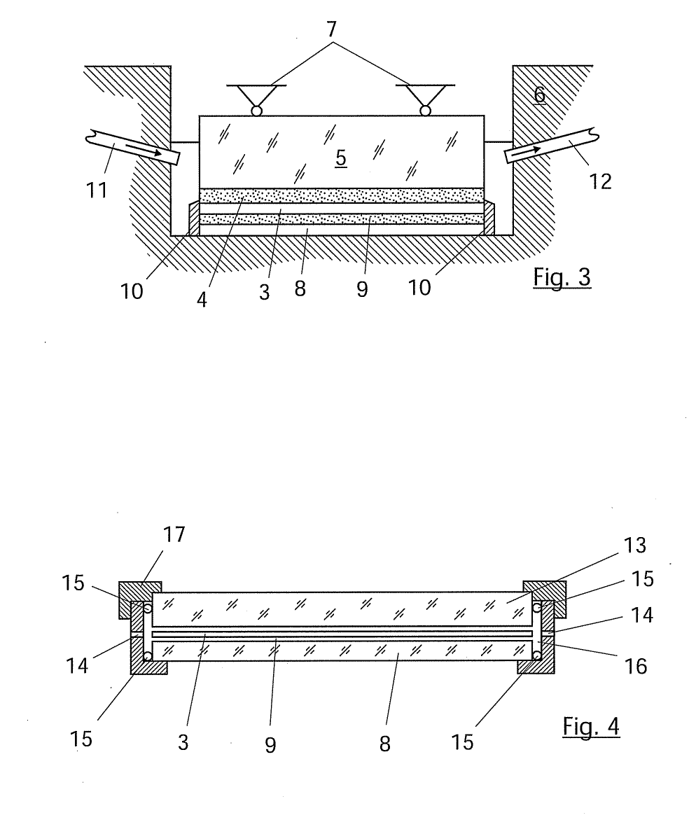

An immersion liquid is subsequently applied to the surface of the crystal plate 3 thus exposed, and a first support plate 8 (illustrated in FIG. 3) is mounted without bubbles, the aim being to keep the immersion film 9 as thin as possible.

Subsequently, the system composed of first support plate 8, immersion film 9, anisotropic crystal plate 3 and second carrier plate 5 is turned and introduced into a solvent container 6 having an inlet 11 and an outlet 12 for the immersion liquid. It is fixed mechanically in this case in the solvent container 6 by means of holders 7 and 10. Subsequently, the solvent container 6 is flushed by means of the immersion liquid, for example alcohol, and this causes the second connecting layer 4 to dissolve.

After the dissolution of the connecting layer 4, the second carrier plate 5 is carefully raised upwards. Since the later final immersion liquid is used as solvent in the present example, it is necessary to ensure a sufficiently high volumetric flow in order to flush out any possible contaminants.

Subsequently, a second support plate 13 can be fed from above, the aim, once again, being to avoid the formation of gas bubbles in the immersion liquid. It has proved effective in this case to immerse the support plate 13 into the immersion liquid obliquely from above.

As soon as the desired thickness of the immersion film is reached, the entire arrangement can be held mechanically.

The phase delay element thus obtained is illustrated in FIG. 4.

The anisotropic crystal plate 3 having a thickness of, for example, in the range from 2 μm to 13 μm, preferably 5 μm to 10 μm, is located surrounded by an immersion film in a mechanical mount 17 sealed by means of O-rings 15. The immersion film in this case has, for example, a thickness of 5 μm to 50 μm, preferably approximately 10 μm. The mechanical mount 17 ensures the plane-parallel alignment of the anisotropic crystal plate 3 with respect to the two support plates 13 and 8. In this case, silica glass constitutes an advantageous selection for the material of the support plates 13 and 8. By way of example, Al₂O₃, MgF₂, SiO₂, or LaF₃ has proved effective as material for the anisotropic crystal plate 3. The mechanical mount 17 exhibits two closable bores 14 that permit the immersion liquid in the immersion space 16 to be replaced or refilled. Cyclohexane, which has a refractive index of 1.556 at 193.3 nm, has proved effective as immersion liquid and solvent.

The invention described therefore permits the provision of mechanically robust, large-area phase delay elements of high quality and long-time stability.

What is claimed is:

1. Method for producing a zeroth-order or low-order phase delay: element, in particular a phase delay element for wavelengths λ<200 nm, the phase delay element being formed from a birefringent crystalline material, in which
a) an anisotropic crystal plate connected via a first connecting layer to a first carrier plate is connected to a second carrier plate on the side averted from the first carrier plate by means of a second connecting layer,
b) after which the two connecting layers are sequentially removed, and
c) an immersion liquid is respectively applied to the exposed surfaces of the anisotropic crystal plate and a support plate is mounted in each case.

2. Method according to claim 1, wherein said anisotropic crystal plate and the two support plates are interconnected mechanically.

3. Method according to claim 1, wherein
a) said first carrier plate is detached in a first step in the region of the first connecting layer, after which
b) said first connecting layer is removed by means of a first solvent, after which
c) the immersion liquid is applied to the exposed first surface of said anisotropic crystal plate, and said first support plate is subsequently mounted, after which
d) said second connecting layer is removed with the aid of a second solvent, and after which
e) said second support plate is mounted on the exposed second surface of the anisotropic crystal plate, immersion liquid likewise being introduced between said second support plate and the second surface of said anisotropic crystal plate.

4. Method according to claim 1, wherein said anisotropic crystal plate connected to said first carrier plate is produced in that
said first carrier plate is firstly provided with a plane-processed surface,
said anisotropic crystal plate is connected to said first carrier plate via the first connecting layer,
after which a large part of the anisotropic crystal plate is detached except for a residual layer, and after which
an end thickness of said anisotropic crystal plate is achieved by means of further production and polishing methods.

5. Method according to claim 1, wherein said first solvent is selected such that it does not attack said second connecting layer.

6. Method according to claim 2, wherein said second solvent is simultaneously used as immersion liquid.

7. Method according to claim 3, wherein said second solvent is an organic solvent.

8. Method according to claim 3, wherein said second solvent is cyclohexane.

9. Method according to claim 1, wherein after the detachment of said first carrier plate residues of said carrier plate remaining on said first connecting layer are removed by a lapping operation.

10. Method according to claim 1, wherein said second connecting layer has a thickness of 0.2-0.5 mm.

11. Zeroth-order or low-order phase delay element, in particular for use in semiconductor lithography, comprising an anisotropic crystal plate, the anisotropic crystal plate being mechanically fixed between two support plates, and an immersion liquid being located between the support plates and the anisotropic crystal plate.

12. Phase delay element according to claim 11, wherein said anisotropic crystal plate is formed from Al₂O₃, MgF₂, SiO₂ or LaF₃.

13. Phase delay element according to claim 11 or 12, wherein said anisotropic crystal plate has a thickness in the range from 2 μm to 13 μm.

14. Phase delay element according to claim 11, wherein an organic liquid is provided as immersion liquid.

15. Phase delay element according to claim 11, wherein said immersion liquid is cyclohexane.

16. Phase delay element according to claim 11, wherein said immersion liquid is formed on both sides of the anisotropic crystal plate as a film with a thickness of 5-50 μm.

17. Phase delay element according to claim 11, wherein said support plates are constructed as silica glass plates.

18. Phase delay element according to claim 11, wherein said support plates and said anisotropic crystal plate are fixed in plane-parallel fashion in a mechanical mount, the mechanical mount sealing from the outside an immersion space, filled with immersion liquid, around the anisotropic crystal plate.

19. Phase delay element according to claim 18, wherein said mechanical mount has at least one closable bore through which immersion liquid can be fed or discharged.
